(19) United States
(12) Patent Application Publication
(10) Pub. No.: US 2025/0253218 A1
(43) Pub. Date: Aug. 7, 2025

(54) SEMICONDUCTOR PACKAGE AND MANUFACTURING METHOD OF SEMICONDUCTOR PACKAGE

(71) Applicant: Samsung Electronics Co., Ltd., Suwon-si (KR)

(72) Inventors: Seong-Hoon Bae, Suwon-si (KR); Hyungjun Park, Suwon-si (KR); Kwangok Jeong, Suwon-si (KR); Wonho Choi, Suwon-si (KR); Hongseo Heo, Suwon-si (KR)

(21) Appl. No.: 18/788,534

(22) Filed: Jul. 30, 2024

(30) Foreign Application Priority Data
Feb. 6, 2024 (KR) 10-2024-0018372

(51) Int. Cl. H01L 23/498; C25D 5/02; C25D 7/12; C25D 21/12; H01L 21/48; H01L 23/00; H01L 23/31; H01L 25/10

(52) U.S. Cl. CPC H01L 23/49811; C25D 5/022; C25D 7/123; C25D 21/12; H01L 21/4853; H01L 24/24; H01L 25/105; H01L 23/3107; H01L 23/49822; H01L 2224/24146; H01L 2225/1058

(57) ABSTRACT

A semiconductor package includes a first redistribution structure, a semiconductor chip on the first redistribution structure, a molding member on the first redistribution structure and the semiconductor chip, a second redistribution structure on the molding member, and a conductive post between the first redistribution structure and the second redistribution structure that electrically connects the first redistribution structure and the second redistribution structure. The conductive post includes a lower portion connected to the first redistribution structure, an upper portion connected to the second redistribution structure, and a middle portion between the lower portion and the upper portion. A width of the middle portion in a horizontal direction, parallel to an upper surface of the first redistribution structure, is not constant.

### CROSS-REFERENCE TO RELATED APPLICATION

This application claims priority to and the benefit under 35 U.S.C. § 119 of Korean Patent Application No. 10-2024-0018372 filed in the Korean Intellectual Property Office on Feb. 6, 2024, the entire contents of which are incorporated herein by reference.

### BACKGROUND

The present disclosure relates generally to a semiconductor package and a manufacturing method of the semiconductor package.

As a semiconductor chip becomes increasingly finer and integration of the semiconductor chip increases, it is required to implement a semiconductor package having a small size and including a plurality of input and output terminals.

One of the package technologies that meets the requirement of a small size and a plurality of input and output terminals is a wafer level package that uses redistribution of a connection pad of a semiconductor chip formed on a wafer. The wafer level package includes a fan-in wafer level package and a fan-out wafer level package. In the fan-out wafer level package, input and output terminals may be disposed outside a region where the semiconductor chip is disposed, so that it is advantageous to implement the fan-out wafer level package that has a small size and includes a plurality of pins.

### SUMMARY

Embodiments of the inventive concept provide a semiconductor package with improved reliability and productivity and a manufacturing method of the semiconductor package.

A semiconductor package according to an embodiment includes: a first redistribution structure; a semiconductor chip on the first redistribution structure; a molding member on the first redistribution structure and the semiconductor chip; a second redistribution structure on the molding member; and a conductive post between the first redistribution structure and the second redistribution structure that connects the first redistribution structure and the second redistribution structure. The conductive post includes a lower portion connected to the first redistribution structure, an upper portion connected to the second redistribution structure, and a middle portion between the lower portion and the upper portion, and a width of the middle portion is not constant.

A semiconductor package according to another embodiment includes: a first redistribution structure; a first semiconductor chip on an upper surface of the first redistribution structure; a molding member on the first redistribution structure and the semiconductor chip; a second redistribution structure on the molding member; a second semiconductor chip on the second redistribution structure; an external connection structure on a lower surface of the first redistribution structure; and a plurality of conductive posts between the first redistribution structure and the second redistribution structure that connect the first redistribution structure to the second redistribution structure. Each of the plurality of conductive posts includes a lower portion connected to the first redistribution structure, an upper portion connected to the second redistribution structure, and a middle portion between the lower portion and the upper portion, a width of the lower portion and a width of the upper portion are constant, and a width of the middle portion is not constant.

A manufacturing method of the semiconductor package according to an embodiment includes: forming a first redistribution structure on one surface of a carrier substrate; forming a seed layer on an upper surface of the first redistribution structure; forming a photoresist pattern including an opening portion on the seed layer; and forming a conductive post by plating a conductive material within the opening portion. The forming of the conductive post includes forming a lower portion of the conductive post by plating with a current density less than a limiting current density, forming a middle portion of the conductive post by plating with a current density greater than the limiting current density, and forming an upper portion of the conductive post by plating with the current density less than the limiting current density, and the limiting current density is a maximum current density at which a plating material completely fills the opening portion.

According to the embodiments, reliability and productivity of a semiconductor package may be improved.

### BRIEF DESCRIPTION OF THE DRAWINGS

FIG. 1 is a schematic cross-sectional view showing a semiconductor package of an embodiment.

FIG. 2 is an enlarged view of the semiconductor package shown in FIG. 1 depicting a region RG of FIG. 1.

FIGS. 3 to 5 are graphs showing a current density (or an electric current density) and a limiting current density according to an aspect ratio of an opening portion in a plating process for forming a conductive post of FIG. 2.

FIG. 6 is a schematic cross-sectional view showing a modified example of a conductive post of the semiconductor package according to one or more embodiments.

FIG. 7 is a graph showing a current density and a limiting current density according to an aspect ratio of an opening portion in a plating process for forming the conductive post of FIG. 6.

FIG. 8 is a schematic cross-sectional view showing a modified example of a conductive post of the semiconductor package according to one or more embodiments.

FIG. 9 is a graph showing a current density and a limiting current density according to an aspect ratio of an opening portion in a plating process for forming the conductive post of FIG. 8.

FIGS. 10 to 18 are schematic cross-sectional views showing intermediate processes in an example manufacturing method of the semiconductor package according to one or more embodiments.

### DETAILED DESCRIPTION

Embodiments of the present disclosure will be described more fully hereinafter with reference to the accompanying drawings so that those skilled in the art easily implement the embodiments, wherein like reference numerals (when used) indicate corresponding elements throughout the several views. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

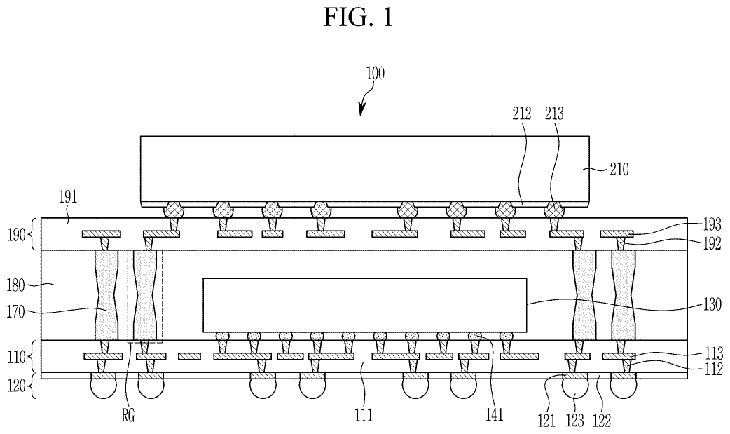

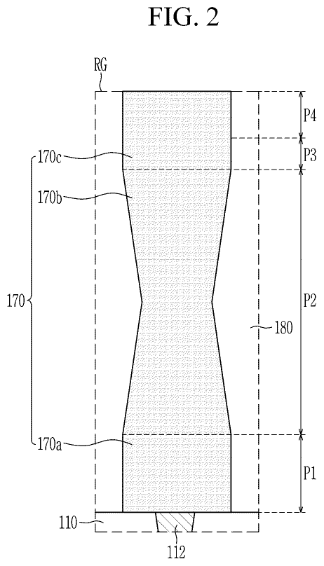

Hereinafter, a semiconductor package according to an embodiment will be described with reference to FIG. 1 and FIG. 2.

FIG. 1 is a schematic cross-sectional view showing the semiconductor package according to one or more embodiments. FIG. 2 is an enlarged view of a region RG of the example semiconductor package shown in FIG. 1.

Referring to FIG. 1 and FIG. 2, a semiconductor package 100 according to an embodiment may include a first redistribution structure 110, an external connection structure 120, a first semiconductor chip 130, a plurality of conductive posts 170, a molding member 180, a second redistribution structure 190, and a second semiconductor chip 210.

In an embodiment, the semiconductor package 100 may include a package-on-package (POP). In an embodiment, the semiconductor package 100 may include a fan-out wafer level package (FOWLP) or a fan-out panel level package (FOPLP).

The first redistribution structure 110 may include a first insulating layer 111, a plurality of first redistribution vias 112, and a plurality of first redistribution lines 113.

The first insulating layer 111 may surround the plurality of first redistribution vias 112 and the plurality of first redistribution lines 113. The term “surround” (or surrounds, or like terms), as may be used herein, is intended to broadly refer to an element, structure or layer that extends around, envelopes, encircles or encloses another element, structure or layer on all sides, although breaks or gaps may be present. Thus, for example, a material layer having voids or gaps therein may still “surround” another layer which it encircles. The first insulating layer 111 may insulate the plurality of first redistribution vias 112 from each other, and may insulate the plurality of first redistribution lines 113 from each other. The first insulating layer 111 may protect the plurality of first redistribution vias 112 and the plurality of first redistribution lines 113.

The first redistribution via 112 may be disposed between the first redistribution line 113 and a conductive pad 121 that is included in the external connection structure 120 and is described later, and may be disposed between the first redistribution line 113 and the conductive post 170. The first redistribution via 112 may connect the first redistribution line 113 and the conductive pad 121 in a vertical direction perpendicular to an upper surface of the first redistribution structure 110, and may connect the first redistribution line 113 and the conductive post 170 in the vertical direction. The term “connect” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The first redistribution via 112 may electrically connect the first redistribution line 113 and the conductive pad 121, and may electrically connect the first redistribution line 113 and the conductive post 170.

The first redistribution via 112 may include the first redistribution via 112 adjacent to a lower surface of the first insulating layer 111 and the first redistribution via 112 adjacent to an upper surface of the first insulating layer 111.

The first redistribution line 113 may extend in a horizontal direction, parallel to the upper surface of the first redistribution structure 110. The first redistribution line 113 may be disposed between the first redistribution via 112 adjacent to the lower surface of the first insulating layer 111 and the first redistribution via 112 adjacent to the upper surface of the first insulating layer 111. The first redistribution line 113 may connect the first redistribution via 112 adjacent to the lower surface of the first insulating layer 111 to the first redistribution via 112 adjacent to the upper surface of the first insulating layer 111 in the horizontal direction. The first redistribution lines 113 may electrically connect the first redistribution via 112 adjacent to the lower surface of the first insulating layer 111 to the first redistribution via 112 adjacent to the upper surface of the first insulating layer 111.

The external connection structure 120 may be disposed on a lower surface of the first redistribution structure 110. The external connection structure 120 may include a plurality of conductive pads 121, a pad insulating layer 122, and a plurality of external connection members 123. The conductive pad 121 may be buried (or embedded) in a lower surface of the pad insulating layer 122 so that a lower surface of the conductive pad 121 is horizontally coplanar with the lower surface of the pad insulating layer 122. The conductive pad 121 may electrically connect the first redistribution via 112 and the external connection member 123. The pad insulating layer 122 may surround (i.e., extend around) side surfaces of the plurality of conductive pads 121. The pad insulating layer 122 may prevent the plurality of conductive pads 121 from being short-circuited with each other. The external connection member 123 may be disposed on the lower surface of the conductive pad 121. The external connection member 123 may electrically connect the semiconductor package 100 to an external device. For example, the external connection member 123 may include a solder ball or a solder bump.

The first semiconductor chip 130 may be disposed on an upper surface of the first redistribution structure 110. However, the embodiment is not limited thereto. In some embodiments, a three-dimensional integrated circuit (3D IC) structure may be disposed on the upper surface of the first redistribution structure 110. The 3D IC structure may include a plurality of semiconductor chips, and may three-dimensionally implement a system-on-chip (SOC). For example, the 3D IC structure may be a structure in which a semiconductor chip including a memory chip, a communication chip, or a sensor is stacked on a semiconductor chip including a central processing unit or a graphics processing unit.

The first semiconductor chip 130 may include a plurality of first connection members 141. The first connection member 141 may electrically connect the first semiconductor chip 130 and the first redistribution structure 110. For example, the first connection member 141 may include a micro-bump.

The plurality of conductive posts 170 may be disposed on the upper surface of the first redistribution structure 110. The plurality of conductive posts 170 may be disposed between the first redistribution structure 110 and the second redistribution structure 190. The plurality of conductive posts 170 may be disposed next to a side surface of the first semiconductor chip 130. The plurality of conductive posts 170 may be spaced apart from the side surface of the first semiconductor chip 130 in a horizontal direction.

The conductive post 170 may extend through the molding member 180 in a direction perpendicular to the upper surface of the first redistribution structure 110. The conductive post 170 may extend from the upper surface of the first redistribution structure 110 to a lower surface of the second redistribution structure 190. The conductive post 170 may connect the first redistribution structure 110 and the second redistribution structure 190 in a vertical direction. The conductive post 170 may have a pillar shape.

The conductive post 170 may include a conductive material. For example, the conductive post 170 may include conductive copper (Cu), but the present disclosure is not limited thereto. The conductive post 170 may electrically connect the first redistribution structure 110 and the second redistribution structure 190. For example, the conductive post 170 may electrically connect the first redistribution via 112 to a second redistribution via 192 that is included in the second redistribution structure 190 and is described later.

For example, a planar shape of the conductive post 170 may be a circular shape, but the present disclosure is not limited thereto. In some embodiments, the planar shape of the conductive post 170 may be an elliptical or polygonal shape.

Referring to FIG. 2, the conductive post 170 may include a lower portion 170a connected to the first redistribution structure 110, an upper portion 170c connected to the second redistribution structure 190, and a middle portion 170b disposed between the lower portion 170a and the upper portion 170c.

According to an embodiment, a width of the middle portion 170b in the horizontal direction may be the same as a width of the lower portion 170a, or may be smaller than the width of the lower portion 170a. The width of the middle portion 170b may be the same as a width of the upper portion 170c in the horizontal direction, or may be smaller than the width of the upper portion 170c. Accordingly, a side surface of the middle portion 170b may have a shape concave toward a center of the conductive post 170.

According to an embodiment, the width of the middle portion 170b may not be constant. According to an embodiment, the width of the middle portion 170b in the horizontal direction may decrease and then increase with increasing distance in the vertical direction from the lower portion 170a to the upper portion 170c. The width of the middle portion 170b in the horizontal direction may be the same as the width of the lower portion 170a at an interface between the middle portion 170b and the lower portion 170a. The width of the middle portion 170b in the horizontal direction may be the same as the width of the upper portion 170c at an interface between the middle portion 170b and the upper portion 170c. The width of the middle portion 170b may decrease as it moves away from the interface between the middle portion 170b and the lower portion 170a. The width of the middle portion 170b may decrease to a change point. Here, the change point may be a point disposed between the interface between the middle portion 170b and the lower portion 170a and the interface between the middle portion 170b and the upper portion 170c. A width of the middle portion 170b in the horizontal direction at the change point may represent a minimum width of the conductive post 170. The width of the middle portion 170b may increase from the change point. The width of the middle portion 170b may increase as it approaches the interface between the middle portion 170b and the upper portion 170c.

The interface between the middle portion 170b and the lower portion 170a and the interface between the middle portion 170b and the upper portion 170c may be conceptually recognized, but the lower portion 170a, the middle portion 170b, and the upper portion 170c may be actually integrated, so that the interface between the middle portion 170b and the lower portion 170a and the interface between the middle portion 170b and the upper portion 170c are not identified.

For example, the width of the middle portion 170b may decrease or increase with a constant slope as a distance from an upper surface of the first redistribution structure 110 increases, but the present disclosure is not limited thereto. As another example, the slope at which the width of the middle portion 170b decreases or increases may vary depending on the vertical distance from the upper surface of the first redistribution structure 110.

According to an embodiment, each of the widths of the lower portion 170a and the upper portion 170c may be constant. Accordingly, a side surface of the lower portion 170a and a side surface of the upper portion 170c may be formed as a plane in a cross-section perpendicular to the upper surface of the first redistribution structure 110.

According to an embodiment, the width of the lower portion 170a may be the same as the width of the upper portion 170c. The width of the lower portion 170a and the width of the upper portion 170c may be a maximum width of the conductive post 170.

According to an embodiment, the conductive post 170 may include a first portion P1, a second portion P2, a third portion P3, and a fourth portion P4. The first portion P1 may correspond to the lower portion 170a of the conductive post 170. The second portion P2 may correspond to the middle portion 170b of the conductive post 170. The third portion P3 and the fourth portion P4 may correspond to the upper portion 170c of the conductive post 170.

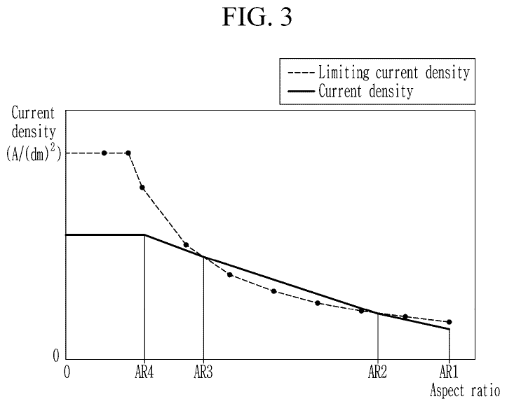

The first portion P1, the second portion P2, the third portion P3, and the fourth portion P4 may be divided according to a method of forming the conductive post 170, and will be described hereinafter with various methods of forming the conductive post 170 with reference to FIGS. 3 to 5.

A side surface of the conductive post 170 may be surrounded by the molding member 180 that will be described later. The conductive post 170 may be disposed to penetrate (i.e., extend into or through) the molding member 180.

The molding member 180 may cover the first redistribution structure 110 and the first semiconductor chip 130. The term “cover” (or “covering,” “covers,” or like terms), as may be used herein, is intended to broadly refer to an element, structure or layer that is on or over another element, structure or layer, either directly or with one or more other intervening elements, structures or layers therebetween.

Referring again to FIG. 1, the second redistribution structure 190 may be disposed on the molding member 180. The second redistribution structure 190 may include a second insulating layer 191, a plurality of second redistribution vias 192, and a plurality of second redistribution lines 193.

The second insulating layer 191 may surround the plurality of second redistribution vias 192 and the plurality of second redistribution lines 193. The second insulating layer 191 may insulate the plurality of second redistribution vias 192 from each other, and may insulate the plurality of second redistribution lines 193 from each other. The second insulating layer 191 may protect the plurality of second redistribution vias 192 and the plurality of second redistribution lines 193.

The second redistribution via 192 may be disposed between the second redistribution line 193 and the conductive post 170, and may be disposed between the second redistribution line 193 and a second connection member 213 that will be described later. The second redistribution via 192 may connect the second redistribution line 193 to the conductive post 170 in a vertical direction, and may connect the second redistribution line 193 to the second connection member 213 in the vertical direction. The second redistribution via 192 may electrically connect the second redistribution line 193 to the conductive post 170, and may electrically connect the second redistribution line 193 to the second connection member 213.

The second redistribution via 192 may include the second redistribution via 192 adjacent to a lower surface of the second insulating layer 191 and the second redistribution via 192 adjacent to an upper surface of the second insulating layer 191.

The second redistribution line 193 may extend in a horizontal direction. The second redistribution line 193 may be disposed between the second redistribution via 192 adjacent to the lower surface of the second insulating layer 191 and the second redistribution via 192 adjacent to the upper surface of the second insulating layer 191. The second redistribution line 193 may connect the second redistribution via 192 adjacent to the lower surface of the second insulating layer 191 to the second redistribution via 192 adjacent to the upper surface of the second insulating layer 191 in the horizontal direction. The second redistribution line 193 may electrically connect the second redistribution via 192 adjacent to the lower surface of the second insulating layer 191 to the second redistribution via 192 adjacent to the upper surface of the second insulating layer 191.

The second semiconductor chip 210 may be disposed on the second redistribution structure 190. For example, the second semiconductor chip 210 may include a single chip such as a dynamic random access memory (DRAM) or a multi-chip such as a high-bandwidth memory (HBM).

The second semiconductor chip 210 may include a plurality of second connection members 213 and an insulating layer 212. The second connection member 213 may electrically connect the second semiconductor chip 210 and the second redistribution structure 190. For example, the second connection member 213 may include a micro-bump or a solder ball. The insulating layer 212 may include a plurality of opening portions. The plurality of second connection members 213 may be connected to the second semiconductor chip 210 through the plurality of opening portions of the insulating layer 212. The insulating layer 212 may prevent the plurality of second connection members 213 from being short-circuited with each other. For example, the insulating layer 212 may include a solder resist.

The semiconductor package 100 according to the embodiment may include the conductive post 170 in which a width of the middle portion 170b is not constant. Thus, the semiconductor package 100 may prevent a crack from occurring at an interface between the conductive post 170 and the molding member 180, and may prevent the crack from propagating through an entire height of the conductive post 170 even if the crack occurs.

The semiconductor package 100 according to one or more embodiments may include the conductive post 170 in which the width of the middle portion 170b in the horizontal direction is not constant. Thus, when the first semiconductor chip 130 is molded at the first redistribution structure 110, a liquid molding member may flow well along a side surface of the conductive post 170.

Hereinafter, various examples of a method of plating the conductive post 170 of FIG. 2 will be described with reference to FIGS. 3 to 5, according to one or more embodiments.

FIGS. 3 to 5 are graphs showing a current density (or an electric current density) and a limiting current density according to an aspect ratio of an opening portion in a plating process for forming the conductive post of FIG. 2.

According to an embodiment, a seed layer and a photoresist layer may be sequentially formed on the first redistribution structure 110 (see FIG. 1), and the photoresist layer may be patterned to form a photoresist pattern including a plurality of opening portions. Thereafter, the conductive posts 170 (see FIGS. 1 and 2) may be formed in the plurality of opening portions of the photoresist pattern through electroplating.

In FIG. 3, an x-axis may correspond to the aspect ratio of the opening portion of the photoresist pattern. The aspect ratio of the opening portion may be a ratio of a height of the opening portion along a direction perpendicular to an upper surface of the first redistribution structure 110 to a width of the opening portion along a direction parallel to the upper surface of the first redistribution structure 110. According to an embodiment, because a plating material is filled within the opening portion as the plating proceeds, the aspect ratio of the opening portion may decrease. The term “filled” (or “filling,” “fills,” or like terms), as may be used herein, is intended to refer broadly to either completely filling a defined space or partially filling the defined space; that is, the defined space need not be entirely filled but may, for example, be partially filled or have voids or other spaces throughout.

According to an embodiment, the aspect ratio of the opening portion before the plating starts may be high. For example, the aspect ratio of the opening portion may exceed 1.5, but the present disclosure is not limited thereto.

In FIG. 3, a y-axis may correspond to the current density. The current density may represent a size (A/(dm)²) of current per unit area. An area that is plated may be a flat area of the opening portion, and may be the same during the plating process. In other words, the current density may correspond to the size of the current.

In FIG. 3, the limiting current density may be a maximum current density at which the plating material may completely fill the opening portion. At the current density less than or equal to the limit current density, the plating material may completely fill the opening portion. At the current density that exceed the limiting current density, the plating material may not completely fill the opening portion. For example, at the current density that exceeds the limiting current density, a plating film may be formed only at a central portion of the opening portion, and may not be formed at an edge of the opening portion. The limiting current density may increase as the aspect ratio of the opening portion decreases. As the aspect ratio of the opening portion decreases, a slope at which the limiting current density increases may increase. The limiting current density may be maintained without further increasing if the aspect ratio of the opening portion becomes smaller than or equal to a threshold value.

According to an embodiment, the plating material may be copper (Cu), but the present disclosure is not limited thereto, and various metal materials may be used as the plating material.

Referring to FIG. 2 and FIG. 3, the current density may be lower than the limiting current density in a first section in which the aspect ratio of the opening portion is between a first aspect ratio AR1 and a second aspect ratio AR2. Because the current density is lower than the limiting current density, the opening portion may be completely filled in the first section. The first portion P1 of the conductive post 170 may be formed corresponding to the first section. A width of the first portion P1 may be the same as a width of the opening portion, and may be constant.

According to an embodiment, the first portion P1 may be formed by applying a current that changes from a first value (i.e., current amplitude or level) to a second value during a first time interval. Here, the first value may be a value of a start current of the first section, and the second value may be a value of an end current of the first section. For example, the current having the first value may be applied at the first aspect ratio AR1, and the current having the second value may be applied at the second aspect ratio AR2. A time interval taken for the aspect ratio of the opening portion to change from the first aspect ratio AR1 to the second aspect ratio AR2 may be the first time interval.

According to an embodiment, the current density may increase in the first section. In other words, the value of the current applied in the first section may increase from the first value to the second value. However, because the current density is lower than the limiting current density in the first section, the opening portion may be completely filled, and the width of the first portion P1 corresponding to the first section may be constant as a width of the opening portion.

According to an embodiment, the first portion P1 of the conductive post 170 may correspond to the lower portion 170a. A width of the lower portion 170a may be constant.

In a second section where the aspect ratio of the opening portion is between the second aspect ratio AR2 and a third aspect ratio AR3, the current density may be higher than the limiting current density. Because the current density is higher than the limiting current density, the opening portion may not be completely filled in the second section. The second portion P2 of the conductive post 170 may be formed corresponding to the second section. A width of the second portion P2 may be smaller than the width of the opening portion, and may not be constant.

According to an embodiment, the second portion P2 may be formed by applying a current that changes from a second value to a third value during a second time interval. Here, the second value may be a value of a start current of the second section, and the third value may be a size of an end current of the second section. The value of the start current of the second section may be the same as the value of the end current of the first section.

For example, the current having the second value may be applied at the second aspect ratio AR2, and the current having the third value current may be applied at the third aspect ratio AR3. A time interval taken for the aspect ratio of the opening portion to change from the second aspect ratio AR2 to the third aspect ratio AR3 may be the second time interval.

According to an embodiment, the current density may increase in the second section. In other words, the value of the current applied in the second section may increase from the second value to the third value.

According to an embodiment, a difference between the current density and the limiting current density may increase and then decrease in the second section. The difference between the current density and the limiting current density in the second section may correspond to a difference between the width of the second portion P2 and the width of the opening portion corresponding to the second section. The difference between the width of the second portion P2 and the width of the opening portion corresponding to the second section may increase and then decrease. An increase in the difference between the width of the second portion P2 and the width of the opening portion may mean a decrease in the width of the second portion P2. A decrease in the difference between the width of the second portion P2 and the width of the opening portion may mean an increase in the width of the second portion P2.

According to an embodiment, the second portion P2 of the conductive post 170 may correspond to the middle portion 170b. A width of the middle portion 170b may decrease and then increase as the aspect ratio of the opening portion decreases. That is, the width of the middle portion 170b may decrease and then increase as it moves away from the lower portion 170a.

In a third section where the aspect ratio of the opening portion is between the third aspect ratio AR3 and a fourth aspect ratio AR4, the current density may be lower than the limiting current density. Because the current density is lower than the limiting current density, the opening portion may be completely filled in the third section. The third portion P3 of the conductive post 170 may be formed corresponding to the third section. A width of the third portion P3 may be the same as a width of the opening portion, and may be constant.

According to an embodiment, the third portion P3 may be formed by applying a current that changes from a third value to a fourth value during a third time interval. Here, the third value may be a value of a start current of the third section, and the fourth value may be a value of an end current of the third section. The value of the start current of the third section may be the same as the value of the end current of the second section.

For example, the current having the third value may be applied at the third aspect ratio AR3, and the current having the fourth value may be applied at the fourth aspect ratio AR4. A time interval taken for the aspect ratio of the opening portion to change from the third aspect ratio AR3 to the fourth aspect ratio AR4 may be the third time interval.

According to an embodiment, the current density may increase in the third section. In other words, the value of the current applied in the third section may increase from the third value to the fourth value. In the third section, the current density may be lower than the limiting current density, so that the opening portion is completely filled and the width of the third portion P3 corresponding to the third section is constant as the width of the opening portion.

In a fourth section where the aspect ratio of the opening portion is between the fourth aspect ratio AR4 and 0, the current density may be less than the limiting current density. Because the current density is less than the limiting current density, the opening portion may be completely filled in the fourth section. The fourth portion P4 of the conductive post 170 may be formed corresponding to the fourth section. A width of the fourth portion P4 may be the same as a width of the opening portion, and may be constant.

According to an embodiment, the fourth portion P4 may be formed by constantly applying a current having a fourth value during a fourth time interval. Here, the fourth value may be a value of a start current and a value of an end current of the fourth section. The fourth value may be the same as the value of the end current of the third section.

For example, the current having the fourth value may be applied at an aspect ratio equal to or less than the fourth aspect ratio AR4. A time interval taken for the aspect ratio of the opening portion to change from the fourth aspect ratio AR4 to 0 may be the fourth time interval.

According to an embodiment, the current density may be constant in the fourth section. In other words, the value of the current applied in the fourth section may be maintained at the fourth value. In the fourth section, the current density may be less than the limiting current density, so that the opening portion is completely filled and the width of the fourth portion P4 corresponding to the fourth section is constant as the width of the opening portion.

According to an embodiment, the third portion P3 and the fourth portion P4 of the conductive post 170 may correspond to the upper portion 170c. Only methods of currents applied in plating processes forming the third portion P3 and the fourth portion P4 may be different, the width of the third portion P3 and the width of the fourth portion P4 may be constant, and the width of the third portion P3 and the width of the fourth portion P4 may be the same. That is, a width of the upper portion 170c may be constant.

According to an embodiment, the plating may be performed by adding a method of applying a current having a constant value for a constant time interval to a method of applying a current whose value changes for a constant time interval. Thus, a time of the plating according to the embodiment may be shortened compared with a comparative example in which plating is performed only by the method of applying the current having the constant size for the constant time interval so that an efficiency of the plating is improved.

According to an embodiment, because the plating is performed so that an aspect ratio section of the opening portion having the current density higher than the limiting current density that is the maximum current density capable of completely filling the opening portion occurs, the time of the plating may be further shortened. According to the embodiment, because a curved portion is formed on a side surface of the conductive post 170, a crack occurring at an interface between the conductive post 170 and the molding member 180 may be prevented, and even if the crack occurs, the crack may be prevented from extending along the interface.

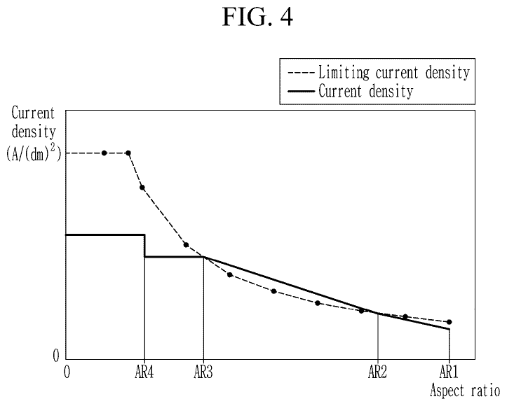

Hereinafter, FIG. 4 will be described focusing on a difference between FIG. 4 and FIG. 3. A method of forming the first portion P1 corresponding to the first section between the first aspect ratio AR1 and the second portion P2 corresponding to the second section between the second aspect ratio AR2 and the third aspect ratio AR3 may be equally applied to the method described with reference to FIG. 3.

Referring to FIG. 4, as shown in FIG. 3, the current density may be lower than the limiting current density in the third section in which the aspect ratio of the opening portion is between the third aspect ratio AR3 and the fourth aspect ratio AR4. Because the current density is lower than the limiting current density, the opening portion may be completely filled in the third section. The third portion P3 of the conductive post 170 may be formed corresponding to the third section. A width of the third portion P3 may be the same as a width of the opening portion, and may be constant.

According to the embodiment shown in FIG. 4, unlike the embodiment shown in FIG. 3, the third portion P3 may be formed by constantly applying a current having a third value during a third time interval. Here, the third value may be a value of a start current and a value of an end current of the third section. The third value may be the same as the value of the end current of the second section.

For example, the current having the third value may be applied at an aspect ratio between the third aspect ratio AR3 and the fourth aspect ratio AR4. A time interval taken for the aspect ratio of the opening portion to change from the third aspect ratio AR3 to the fourth aspect ratio AR4 may be the third time interval.

According to an embodiment, the current density may be constant in the third section. In other words, the value of the current applied in the third section may be constant as the third value. In the third section, the current density may be lower than the limiting current density, so that the opening portion is completely filled and the width of the third portion P3 corresponding to the third section is constant as the width of the opening portion.

Referring to FIG. 4, as shown in FIG. 3, in the fourth section where the aspect ratio of the opening portion is between the fourth aspect ratio AR4 and 0, the current density may be less than the limiting current density. Because the current density is less than the limiting current density, the opening portion may be completely filled in the fourth section. The fourth portion P4 of the conductive post 170 may be formed corresponding to the fourth section. A width of the fourth portion P4 may be the same as a width of the opening portion, and may be constant.

According to the embodiment shown in FIG. 4, unlike the embodiment shown in FIG. 3, the fourth portion P4 may be formed by constantly applying a current having a fourth value during a fourth time interval. Here, the fourth value may be a value of a start current and a value of an end current of the fourth section. The fourth value may be greater than the third value.

For example, the current having the fourth value may be applied at an aspect ratio equal to or less than the fourth aspect ratio AR4. A time interval taken for the aspect ratio of the opening portion to change from the fourth aspect ratio AR4 to 0 may be the fourth time interval.

According to an embodiment, the current density may be constant in the fourth section. In other words, the value of the current applied in the fourth section may be maintained at the fourth value. In the fourth section, the current density may be less than the limiting current density, so that the opening portion is completely filled and the width of the fourth portion P4 corresponding to the fourth section is constant as the width of the opening portion.

According to an embodiment, the third portion P3 and the fourth portion P4 of the conductive post 170 may correspond to the upper portion 170c. Only values of currents applied in plating processes forming the third portion P3 and the fourth portion P4 may be different, the width of the third portion P3 and the width of the fourth portion P4 may be constant, and the width of the third portion P3 and the width of the fourth portion P4 may be the same. That is, a width of the upper portion 170c may be constant.

The third time interval that is a time interval when the current is applied in the third section, the fourth time interval that is a time interval when the current is applied in the fourth section, and the fourth value that is a value of the current applied in the fourth section of the embodiment of FIG. 4 may be different from the third time interval, the fourth time interval, and the fourth value of the embodiment of FIG. 3, respectively.

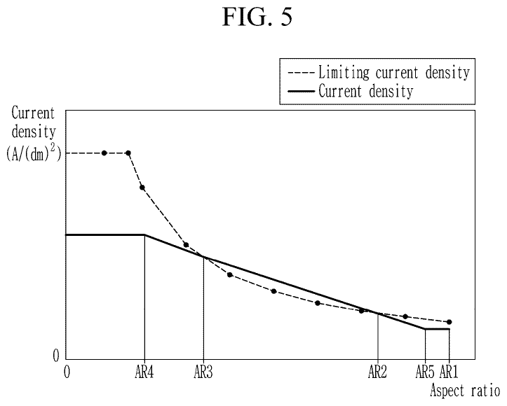

Hereinafter, FIG. 5 will be described focusing on a difference between FIG. 5 and FIG. 3. A method of forming the second portion P2 corresponding to the second section between the second aspect ratio AR2 and the third aspect ratio AR3, the third portion P3 corresponding to the third section between the third aspect ratio AR3 and the fourth aspect ratio AR4, and the fourth portion P4 corresponding to the fourth section equal to or less than the fourth aspect ratio AR4 may be equally applied to the method described with reference to FIG. 3.

Referring to FIG. 5, as shown in FIG. 3, the current density may be lower than the limiting current density in the first section in which the aspect ratio of the opening portion is between the first aspect ratio AR1 and the second aspect ratio AR2. Because the current density is lower than the limiting current density, the opening portion may be completely filled in the first section. The first portion P1 of the conductive post 170 may be formed corresponding to the first section. A width of the first portion P1 may be the same as a width of the opening portion, and may be constant.

According to the embodiment shown in FIG. 5, unlike the embodiment shown in FIG. 3, the first section may include a first sub-section between first aspect ratio AR1 and a fifth aspect ratio AR5 and a second sub-section between the fifth aspect ratio AR5 and the second aspect ratio AR2. The fifth aspect ratio AR5 may be an aspect ratio between the first aspect ratio AR1 and the second aspect ratio AR2. The first portion P1 may include a portion corresponding to the first sub-section and a portion corresponding to the second sub-section.

According to an embodiment, the portion corresponding to the first sub-section may be formed by constantly applying a current having a first value during a fifth time interval, and the portion corresponding to the second sub-section may be formed by applying a current changing from the first value to a second value during a sixth time interval. The first value may be a value of a start current of the first section, and the second value may be a value of an end current of the first section.

For example, the current having the first value may be applied between the first aspect ratio AR1 and the fifth aspect ratio AR5. A time interval taken for the aspect ratio of the opening portion to change from the first aspect ratio AR1 to the second aspect ratio AR2 may be the fifth time interval. The current having the first value may be applied at the fifth aspect ratio AR5, and the current having the second value may be applied at the second aspect ratio AR2. A time interval taken for the aspect ratio of the opening portion to change from the fifth aspect ratio AR5 to the second aspect ratio AR2 may be the fifth time interval.

According to an embodiment, the current density may be constant in the first sub-section, and the current density may increase in the second sub-section. In other words, the value of the current applied in the first sub-section may be constant as the first value, and the value of the current applied in the second sub-section may increase from the first value to the second value. However, the current density in the first sub-section and the second sub-section may be lower than the limiting current density, so that the opening portion is completely filled and the width of the first portion P1 corresponding to the first sub-section and the second sub-section is constant as the width of the opening portion.

According to an embodiment, the first portion P1 of the conductive post 170 may correspond to the lower portion 170a. A width of the lower portion 170a may be constant.

The first value that is the value of the start current applied in the first section in the embodiment of FIG. 5 may be different from the first value in the embodiment of FIG. 3. Additionally, a sum of the fifth time interval that is a time interval when the current is applied in the first sub-section and the sixth time interval that is a time interval when the current is applied in the second sub-section in the embodiment of FIG. 5 may be different from the first time interval.

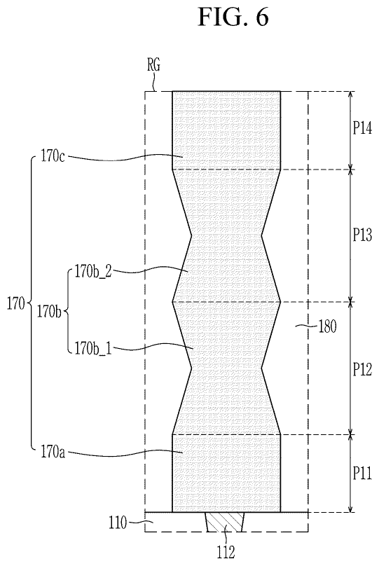

Hereinafter, a modified example of the conductive post 170 of the semiconductor package 100 according to the embodiment will be described with reference to FIG. 6.

FIG. 6 is a schematic cross-sectional view showing the modified example of the conductive post of the semiconductor package according to one or more embodiments. As shown in FIG. 2, FIG. 6 may represent a region corresponding to RG of FIG. 1. Hereinafter, a description of the embodiment of FIG. 6 overlapping the description of the embodiment of FIG. 2 will be omitted or briefly described, and a difference between the embodiment of FIG. 2 and the embodiment of FIG. 6 will be mainly described.

Referring to FIG. 6, the conductive post 170 may include a lower portion 170a connected to the first redistribution structure 110, an upper portion 170c connected to the second redistribution structure 190 (see FIG. 1), and a middle portion 170b disposed between the lower portion 170a and the upper portion 170c.

According to an embodiment, the middle portion 170b may include a first middle portion 170b_1 and a second middle portion 170b_2. The first middle portion 170b_1 and the second middle portion 170b_2 may be disposed in a vertical direction on an upper surface of the first redistribution structure 110. For example, as shown in FIG. 6, the first middle portion 170b_1 may be connected to the lower portion 170a, and the second middle portion 170b_2 may be connected to the upper portion 170c.

According to an embodiment, a width of the first middle portion 170b_1 in the horizontal direction and a width of the second middle portion 170b_2 may be the same as a width of the lower portion 170a, or may be smaller than the width of the lower portion 170a. The width of the first middle portion 170b_1 and the width of the second middle portion 170b_2 may be the same as a width of the upper portion 170c, or may be smaller than the width of the upper portion 170c. Accordingly, each of a side surface of the first middle portion 170b_1 and a side surface of the second middle portion 170b_2 may have a shape concave toward a center of the conductive post 170.

According to an embodiment, each of the width of the first middle portion 170b_1 and the width of the second middle portion 170b_2 may not be constant. According to an embodiment, the width of the first middle portion 170b_1 may decrease and then increase with increasing distance in the vertical direction from the lower portion 170a to the upper portion 170c.

The width of the first middle portion 170b_1 may be the same as the width of the lower portion 170a at an interface between the first middle portion 170b_1 and the lower portion 170a. The width of the first middle portion 170b_1 may decrease as it moves away (i.e., upwardly) from the interface between the first middle portion 170b_1 and the lower portion 170a. The width of the first middle portion 170b_1 may be reduced to a first change point. Here, the first change point may be a point disposed between the interface between the first middle portion 170b_1 and the lower portion 170a and an interface between the first middle portion 170b_1 and the second middle portion 170b_2. The width of the first middle portion 170b_1 may increase from the first change point to the interface between the first middle portion 170b_1 and the second middle portion 170b_2. The width of the first middle portion 170b_1 may be the same as the width of the lower portion 170a or may be smaller than the width of the lower portion 170a at the interface between the first middle portion 170b_1 and the second middle portion 170b_2.

According to an embodiment, the width of the second middle portion 170b_2 may decrease and then increase from the lower portion 170a to the upper portion 170c. The width of the second middle portion 170b_2 may decrease and then increase from the interface between the second middle portion 170b_2 and the first middle portion 170b_1 to an interface between the second middle portion 170b_2 and the upper portion 170c.

The width of the second middle portion 170b_2 may decrease as it moves away (i.e., upwardly) from the interface between the second middle portion 170b_2 and the first middle portion 170b_1. The width of the second middle portion 170b_2 may decrease to a second change point. Here, the second change point may be a point disposed between the interface between the second middle portion 170b_2 and the first middle portion 170b_1 and the interface between the second middle portion 170b_2 and the upper portion 170c. The width of the second middle portion 170b_2 may increase from the second change point. The width of the second middle portion 170b_2 may increase as it approaches the interface between the second middle portion 170b_2 and the upper portion 170c. The width of the second middle portion 170b_2 may increase from the second change point to the interface between the second middle portion 170b_2 and the upper portion 170c. The width of the second middle portion 170b_2 may be the same as the width of the upper portion 170c at the interface between the second middle portion 170b_2 and the upper portion 170c.

The interface between the first middle portion 170b_1 and the lower portion 170a, the interface between the first middle portion 170b_1 and the second middle portion 170b_2, and the interface between the second middle portion 170b_2 and the upper portion 170c may be conceptually recognized, but the lower portion 170a, the first middle portion 170b_1, the second middle portion 170b_2, and the upper portion 170c may be actually integrated, so that the interface between the first middle portion 170b_1 and the lower portion 170a, the interface between the first middle portion 170b_1 and the second middle portion 170b_2, and the interface between the second middle portion 170b_2 and the upper portion 170c are not identified.

According to an embodiment, the conductive post 170 may include a first portion P11, a second portion P12, a third portion P13, and a fourth portion P14. The first portion P11 may correspond to the lower portion 170a of the conductive post 170. The second portion P12 may correspond to the first middle portion 170b_1 of the conductive post 170. The third portion P13 may correspond to the second middle portion 170b_2 of the conductive post 170. The fourth portion P14 may correspond to the upper portion 170c of the conductive post 170.

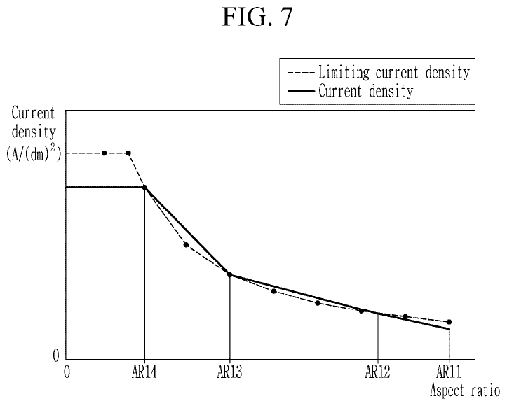

The first portion P11, the second portion P12, the third portion P13, and the fourth portion P14 may be divided according to a method of forming the conductive post 170, and will be described hereinafter with the method of forming the conductive post 170 with reference to FIG. 7.

Hereinafter, a method of plating the conductive post of FIG. 6 will be described with reference to FIG. 7.

FIG. 7 is a graph showing a current density and a limiting current density according to an aspect ratio of an opening portion in a plating process for forming the conductive post of FIG. 6.

Referring to FIG. 6 and FIG. 7, the current density may be lower than the limiting current density in a first section in which the aspect ratio of the opening portion is between a first aspect ratio AR11 and a second aspect ratio AR12. Because the current density is lower than the limiting current density, the opening portion may be completely filled in the first section. The first portion P11 of the conductive post 170 may be formed corresponding to the first section. A width of the first portion P11 may be the same as a width of the opening portion, and may be constant.

According to an embodiment, the first portion P11 may be formed by applying a current that changes from a first value to a second value during a first time interval. Here, the first value may be a value of a start current of the first section, and the second value may be a value of an end current of the first section. For example, the current having the first value may be applied at the first aspect ratio AR11, and the current having the second value may be applied at the second aspect ratio AR12. A time interval taken for the aspect ratio of the opening portion to change from the first aspect ratio AR11 to the second aspect ratio AR12 may be the first time interval.

According to an embodiment, the current density may increase in the first section. In other words, the amplitude of the current applied in the first section may increase from the first value to the second value. However, because the current density is lower than the limiting current density in the first section, the opening portion may be completely filled, and the width of the first portion P11 corresponding to the first section may be constant as a width of the opening portion.

According to an embodiment, the first portion P11 of the conductive post 170 may correspond to the lower portion 170a. A width of the lower portion 170a may be constant.

In a second section where the aspect ratio of the opening portion is between the second aspect ratio AR12 and a third aspect ratio AR13, the current density may be higher than the limiting current density. Because the current density is higher than the limiting current density, the opening portion may not be completely filled in the second section. The second portion P12 of the conductive post 170 may be formed corresponding to the second section. A width of the second portion P12 may be smaller than the width of the opening portion, and may not be constant.

According to an embodiment, the second portion P12 may be formed by applying a current that changes from a second value to a third value during a second time interval. Here, the second value may be a value of a start current of the second section, and the third value may be a value of an end current of the second section.

The value of the start current of the second section may be the same as the value of the end current of the first section.

For example, the current having the second value may be applied at the second aspect ratio AR12, and the current having the third value may be applied at the third aspect ratio AR13. A time interval taken for the aspect ratio of the opening portion to change from the second aspect ratio AR12 to the third aspect ratio AR13 may be the second time interval.

According to an embodiment, the current density may increase in the second section. In other words, the amplitude of the current applied in the second section may increase from the second value to the third value.

According to an embodiment, a difference between the current density and the limiting current density may increase and then decrease in the second section. The difference between the current density and the limiting current density in the second section may correspond to a difference between the width of the second portion P12 and the width of the opening portion corresponding to the second section. The difference between the width of the second portion P12 and the width of the opening portion corresponding to the second section may increase and then decrease. An increase in the difference between the width of the second portion P12 and the width of the opening portion may mean a decrease in the width of the second portion P12. A decrease in the difference between the width of the second portion P12 and the width of the opening portion may mean an increase in the width of the second portion P12.

According to an embodiment, the second portion P12 of the conductive post 170 may correspond to the first middle portion 170b_1. A width of the first middle portion 170b_1 may decrease and then increase as the aspect ratio of the opening portion decreases. That is, the width of the first middle portion 170b_1 may decrease and then increase as it moves away from the lower portion 170a.

In a third section where the aspect ratio of the opening portion is between the third aspect ratio AR13 and a fourth aspect ratio AR14, the current density may be higher than the limiting current density. Because the current density is higher than the limiting current density, the opening portion may not be completely filled in the third section. The third portion P13 of the conductive post 170 may be formed corresponding to the third section. A width of the third portion P13 may be smaller than the width of the opening portion, and may not be constant.

According to an embodiment, the third portion P13 may be formed by applying a current that changes from a third value to a fourth value during a third time interval. Here, the third value may be a value of a start current of the third section, and the fourth value may be a value of an end current of the third section. The value of the start current of the third section may be the same as the size of the end current of the second section.

For example, the current having the third value may be applied at the third aspect ratio AR13, and the current having the fourth value may be applied at the fourth aspect ratio AR14. A time interval taken for the aspect ratio of the opening portion to change from the third aspect ratio AR13 to the fourth aspect ratio AR14 may be the third time interval.

According to an embodiment, the current density may increase in the third section. In other words, the amplitude of the current applied in the third section may increase from the third value to the fourth value.

According to an embodiment, a difference between the current density and the limiting current density may increase and then decrease in the third section. The difference between the current density and the limiting current density in the third section may correspond to a difference between the width of the third portion P13 and the width of the opening portion corresponding to the third section. The difference between the width of the third portion P13 and the width of the opening portion corresponding to the third section may increase and then decrease. An increase in the difference between the width of the third portion P13 and the width of the opening portion may mean a decrease in the width of the third portion P13. A decrease in the difference between the width of the third portion P13 and the width of the opening portion may mean an increase in the width of the third portion P13.

According to an embodiment, the third portion P13 of the conductive post 170 may correspond to the second middle portion 170b_2. A width of the second middle portion 170b_2 may decrease and then increase as the aspect ratio of the opening portion decreases. That is, the width of the second middle portion 170b_2 may decrease and then increase as it moves away from the lower portion 170a. The width of the second middle portion 170b_2 may decrease and then increase as it moves away from the first middle portion 170b_1.

In a fourth section where the aspect ratio of the opening portion is between the fourth aspect ratio AR14 and 0, the current density may be less than the limiting current density. Because the current density is less than the limiting current density, the opening portion may be completely filled in the fourth section. The fourth portion P14 of the conductive post 170 may be formed corresponding to the fourth section. A width of the fourth portion P14 may be the same as a width of the opening portion, and may be constant.

According to an embodiment, the fourth portion P14 may be formed by constantly applying a current having a fourth value during a fourth time interval. Here, the fourth value may be a value of a start current and a value of an end current of the fourth section. The fourth value may be the same as the value of the end current of the third section.

For example, the current having the fourth value may be applied at an aspect ratio equal to or less than the fourth aspect ratio AR14. A time interval taken for the aspect ratio of the opening portion to change from the fourth aspect ratio AR14 to 0 may be the fourth time interval.

According to an embodiment, the current density may be constant in the fourth section. In other words, the amplitude of the current applied in the fourth section may be maintained at the fourth value. In the fourth section, the current density may be less than the limiting current density, so that the opening portion is completely filled and the width of the fourth portion P14 corresponding to the fourth section is constant as the width of the opening portion.

According to an embodiment, the fourth portion P14 of the conductive post 170 may correspond to the upper portion 170c. A width of the upper portion 170c may be constant.

In the embodiment shown in FIG. 7, unlike the embodiment shown in FIGS. 3 to 5, the current density may not be changed in an aspect ratio section corresponding to the upper portion 170c of the conductive post 170, and may be kept constant in an entire section.

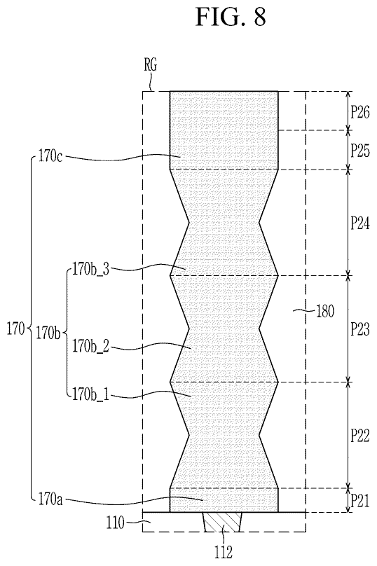

Hereinafter, a modified example of the conductive post 170 of the semiconductor package 100 according to the embodiment will be described with reference to FIG. 8.

FIG. 8 is a schematic cross-sectional view showing a modified example of the conductive post of the semiconductor package of the embodiment. As shown in FIG. 2, FIG. 8 may represent a region corresponding to RG of FIG. 1. Hereinafter, a description of the embodiment of FIG. 8 overlapping the description of the embodiment of FIG. 2 will be omitted or briefly described, and a difference between the embodiment of FIG. 2 and the embodiment of FIG. 8 will be mainly described.

Referring to FIG. 8, the conductive post 170 may include a lower portion 170a connected to the first redistribution structure 110, an upper portion 170c connected to the second redistribution structure 190 (see FIG. 1), and a middle portion 170b disposed between the lower portion 170a and the upper portion 170c.

According to an embodiment, the middle portion 170b may include a first middle portion 170b_1, a second middle portion 170b_2, and a third middle portion 170b_3. The first middle portion 170b_1, the second middle portion 170b_2, and the third middle portion 170b_3 may be disposed in a vertical direction on an upper surface of the first redistribution structure 110. For example, as shown in FIG. 8, the first middle portion 170b_1 may be connected to the lower portion 170a, and the third middle portion 170b_3 may be connected to the upper portion 170c. The second middle portion 170b_2 may be disposed between the first middle portion 170b_1 and the third middle portion 170b_3.

According to an embodiment, a width of the first middle portion 170b_1, a width of the second middle portion 170b_2, and a width of the third middle portion 170b_3 may be the same as a width of the lower portion 170a, or may be smaller than the width of the lower portion 170a. The width of the first middle portion 170b_1, the width of the second middle portion 170b_2, and the width of the third middle portion 170b_3 may be the same as a width of the upper portion 170c, or may be smaller than the width of the upper portion 170c. Accordingly, each of a side surface of the first middle portion 170b_1, a side surface of the second middle portion 170b_2, and a side surface of the third middle portion 170b_3 may have a shape concave toward a center of the conductive post 170.

According to an embodiment, each of the width of the first middle portion 170b_1, the width of the second middle portion 170b_2, and the width of the third middle portion 170b_3 may not be constant. According to an embodiment, the width of the first middle portion 170b_1 in the horizontal direction may decrease and then increase with increasing distance in the vertical direction from the lower portion 170a to the upper portion 170c.

The width of the first middle portion 170b_1 may be the same as the width of the lower portion 170a at an interface between the first middle portion 170b_1 and the lower portion 170a. The width of the first middle portion 170b_1 may decrease as it moves away from the interface between the first middle portion 170b_1 and the lower portion 170a. The width of the first middle portion 170b_1 may decrease to a first change point. Here, the first change point may be a point disposed between the interface between the first middle portion 170b_1 and the lower portion 170a and an interface between the first middle portion 170b_1 and the second middle portion 170b_2. The width of the first middle portion 170b_1 may increase from the first change point to the interface between the first middle portion 170b_1 and the second middle portion 170b_2. The width of the first middle portion 170b_1 may be the same as the width of the lower portion 170a or may be smaller than the width of the lower portion 170a at the interface between the first middle portion 170b_1 and the second middle portion 170b_2.

According to an embodiment, the width of the second middle portion 170b_2 may decrease and then increase from the lower portion 170a to the upper portion 170c. The width of the second middle portion 170b_2 may decrease and then increase from an interface between the second middle portion 170b_2 and the first middle portion 170b_1 to an interface between the second middle portion 170b_2 and the third middle portion 170b_3.

The width of the second middle portion 170b_2 may decrease as it moves away from the interface between the second middle portion 170b_2 and the first middle portion 170b_1. The width of the second middle portion 170b_2 may decrease to a second change point. Here, the second change point may be a point disposed between the interface between the second middle portion 170b_2 and the first middle portion 170b_1 and the interface between the second middle portion 170b_2 and the third middle portion 170b_3. The width of the second middle portion 170b_2 may increase from the second change point. The width of the second middle portion 170b_2 may increase as it approaches the interface between the second middle portion 170b_2 and the third middle portion 170b_3. The width of the second middle portion 170b_2 may increase from the second change point to the interface between the second middle portion 170b_2 and the third middle portion 170b_3. The width of the second middle portion 170b_2 may be the same as the width of the lower portion 170a or may be smaller than the width of the lower portion 170a at the interface between the second middle portion 170b_2 and the third middle portion 170b_3.

According to an embodiment, the width of the third middle portion 170b_3 may decrease and then increase from the lower portion 170a to the upper portion 170c. The width of the third middle portion 170b_3 may decrease and then increase from an interface between the third middle portion 170b_3 and the second middle portion 170b_2 to an interface between the third middle portion 170b_3 and the upper portion 170c.

The width of the third middle portion 170b_3 may decrease as it moves away from the interface between the third middle portion 170b_3 and the second middle portion 170b_2. The width of the third middle portion 170b_3 may decrease to a third change point. Here, the third change point may be a point disposed between the interface between the third middle portion 170b_3 and the second middle portion 170b_2 and the interface between the third middle portion 170b_3 and the upper portion 170c. The width of the third middle portion 170b_3 may increase from the third change point. The width of the third middle portion 170b_3 may increase as it approaches the interface between the third middle portion 170b_3 and the upper portion 170c. The width of the third middle portion 170b_3 may increase from the third change point to the interface between the third middle portion 170b_3 and the upper portion 170c. The width of the third middle portion 170b_3 may be the same as the width of the upper portion 170c at the interface between the third middle portion 170b_3 and the upper portion 170c.

The interface between the first middle portion 170b_1 and the lower portion 170a, the interface between the first middle portion 170b_1 and the second middle portion 170b_2, the interface between the second middle portion 170b_2 and the third middle portion 170b_3, and the interface between the third middle portion 170b_3 and the upper portion 170c may be conceptually recognized, but the lower portion 170a, the first middle portion 170b_1, the second middle portion 170b_2, the third middle portion 170b_3, and the upper portion 170c may be actually integrated, so that the interface between the first middle portion 170b_1 and the lower portion 170a, the interface between the first middle portion 170b_1 and the second middle portion 170b_2, the interface between the second middle portion 170b_2 and the third middle portion 170b_3, and the interface between the third middle portion 170b_3 and the upper portion 170c are not identified.

According to an embodiment, the conductive post 170 may include a first portion P21, a second portion P22, a third portion P23, a fourth portion P24, a fifth portion P25, and a sixth portion P26. The first portion P21 may correspond to the lower portion 170a of the conductive post 170. The second portion P22 may correspond to the first middle portion 170b_1 of the conductive post 170. The third portion P23 may correspond to the second middle portion 170b_2 of the conductive post 170. The fourth portion P24 may correspond to the third middle portion 170b_3 of the conductive post 170. The fifth portion P25 and the sixth portion P26 may correspond to the upper portion 170c of the conductive post 170.

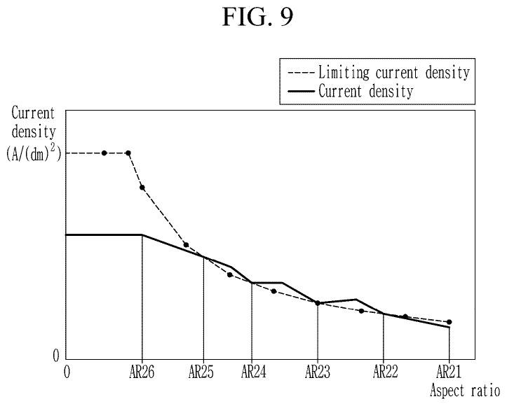

The first portion P21, the second portion P22, the third portion P23, the fourth portion P24, the fifth portion P25, and the sixth portion P26 may be divided according to a method of forming the conductive post 170, and will be described hereinafter with the method of forming the conductive post 170 with reference to FIG. 9.

Although an entire width of the middle portion 170b is not constant in the embodiment shown in FIG. 8, the present disclosure is not limited thereto. For example, in some embodiments, a portion with a constant width may be added between the first middle portion 170b_1 and the second middle portion 170b_2 or between the second middle portion 170b_2 and the third middle portion 170b_3.

Hereinafter, a method of plating the conductive post of FIG. 8 will be described with reference to FIG. 9, according to one or more embodiments.

FIG. 9 is a graph showing a current density and a limiting current density according to an aspect ratio of an opening portion in a plating process for forming the conductive post of FIG. 8.

Referring to FIG. 8 and FIG. 9, the current density may be lower than the limiting current density in a first section in which the aspect ratio of the opening portion is between a first aspect ratio AR21 and a second aspect ratio AR22. Because the current density is lower than the limiting current density, the opening portion may be completely filled in the first section. The first portion P21 of the conductive post 170 may be formed corresponding to the first section. A width of the first portion P21 in the horizontal direction may be the same as a width of the opening portion, and may be constant.

According to an embodiment, the first portion P21 may be formed by applying a current that changes from a first value to a second value during a first time interval. Here, the first value may be a value of a start current of the first section, and the second value may be a value of an end current of the first section. For example, the current having the first value may be applied at the first aspect ratio AR21, and the current having the second value may be applied at the second aspect ratio AR22. A time interval taken for the aspect ratio of the opening portion to change from the first aspect ratio AR21 to the second aspect ratio AR22 may be the first time interval.

According to an embodiment, the current density may increase in the first section. In other words, the amplitude of the current applied in the first section may increase from the first value to the second value. However, because the current density is lower than the limiting current density in the first section, the opening portion may be completely filled, and the width of the first portion P21 corresponding to the first section may be constant as a width of the opening portion.

According to an embodiment, the first portion P21 of the conductive post 170 may correspond to the lower portion 170a. A width of the lower portion 170a may be constant.

In a second section where the aspect ratio of the opening portion is between the second aspect ratio AR22 and a third aspect ratio AR23, the current density may be higher than the limiting current density. Because the current density is higher than the limiting current density, the opening portion may not be completely filled in the second section. The second portion P22 of the conductive post 170 may be formed corresponding to the second section. A width of the second portion P22 may be smaller than the width of the opening portion, and may not be constant.

According to an embodiment, the second portion P22 may be formed by applying a current that changes from the second value to a third value during a second time interval. Here, the second value may be a value of a start current of the second section, and the third value may be a value of an end current of the second section. The value of the start current of the second section may be the same as the value of the end current of the first section.

According to an embodiment, the current density may increase and then decrease in the second section. According to an embodiment, the second section may include a first sub-section in which a difference between the current density and the limiting current density increases and a second sub-section in which the difference between the current density and the limiting current density decreases. An increase in the difference between the current density and the limiting current density in the second section may mean a decrease in the width of the second portion P22. A decrease in the difference between the current density and the limiting current density in the second section may mean an increase in the width of the second portion P22. The first sub-section may correspond to a portion where the width of the second portion P22 decreases. The second sub-section may correspond to a portion where the width of the second portion P22 increases.

According to an embodiment, the portion where the width of the second portion P22 decreases may be formed by applying a current that increases from the second value to a first threshold value during a third time interval. The first threshold value may be a value of a current corresponding to the current density for forming a plating film with a minimum width in which the conductive post 170 may electrically operate at an aspect ratio between the second aspect ratio AR22 and the third aspect ratio AR23.

According to an embodiment, the portion where the width of the second portion P22 increases may be formed by applying a current that increases from the first threshold value to the third value during a fourth time interval. For example, the first threshold value may be larger than the third value, but the present disclosure is not limited thereto.

According to an embodiment, a sum of the third time interval and the fourth time interval may be the second time interval.

According to an embodiment, the second portion P22 of the conductive post 170 may correspond to the first middle portion 170b_1. A width of the first middle portion 170b_1 may decrease and then increase as the aspect ratio of the opening portion decreases. That is, the width of the first middle portion 170b_1 may decrease and then increase as it moves away from the lower portion 170a.

In a third section where the aspect ratio of the opening portion is between the third aspect ratio AR23 and a fourth aspect ratio AR24, the current density may be higher than the limiting current density. Because the current density is higher than the limiting current density, the opening portion may not be completely filled in the third section. The third portion P23 of the conductive post 170 may be formed corresponding to the third section. A width of the third portion P23 may be smaller than the width of the opening portion, and may not be constant.

According to an embodiment, the third portion P23 may be formed by applying a current that changes from the third value to a fourth value during a fifth time interval. Here, the third value may be a value of a start current of the third section, and the fourth value may be a value of an end current of the third section. The value of the start current of the third section may be the same as the value of the end current of the second section.

According to an embodiment, the current density may increase and then decrease in the third section. According to an embodiment, the third section may include a third sub-section in which the difference between the current density and the limiting current density increases and a fourth sub-section in which the difference between the current density and the limiting current density decreases. An increase in the difference between the current density and the limiting current density in the third section may mean a decrease in the width of the third portion P23. A decrease in the difference between the current density and the limiting current density in the third section may mean an increase in the width of the third portion P23. The third sub-section may correspond to a portion where the width of the third portion P23 decreases. The fourth sub-section may correspond to a portion where the width of the third portion P23 increases.

According to an embodiment, the portion where the width of the third portion P23 decreases may be formed by applying a current that increases from the third value to a second threshold value during a sixth time interval. The second threshold value may be a value of a current corresponding to the current density for forming a plating film with a minimum width in which the conductive post 170 may electrically operate at an aspect ratio between the third aspect ratio AR23 and the fourth aspect ratio AR24.

According to an embodiment, the portion where the width of the third portion P23 increases may be formed by applying a current that increases from the second threshold value to the fourth value during a seventh time interval. For example, the second threshold value may be the same as the fourth value, but the present disclosure is not limited thereto.

According to an embodiment, a sum of the sixth time interval and the seventh time interval may be the fifth time interval.

According to an embodiment, the third portion P23 of the conductive post 170 may correspond to the second middle portion 170b_2. A width of the second middle portion 170b_2 may decrease and then increase as the aspect ratio of the opening portion decreases. That is, the width of the second middle portion 170b_2 may decrease and then increase as it moves away from the first middle portion 170b_1.

In a fourth section where the aspect ratio of the opening portion is between the fourth aspect ratio AR24 and a fifth aspect ratio AR25, the current density may be higher than the limiting current density. Because the current density is higher than the limiting current density, the opening portion may not be completely filled in the fourth section. The fourth portion P24 of the conductive post 170 may be formed corresponding to the fourth section. A width of the fourth portion P24 may be smaller than the width of the opening portion, and may not be constant.

According to an embodiment, the fourth portion P24 may be formed by applying a current that changes from the fourth value to a fifth value during an eighth time interval. Here, the fourth value may be a value of a start current of the fourth section, and the fifth value may be a value of an end current of the fourth section. The value of the start current of the fourth section may be the same as the value of the end current of the third section.

According to an embodiment, the current density may increase and then decrease in the fourth section. According to an embodiment, the fourth section may include a fifth sub-section in which the difference between the current density and the limiting current density increases and a sixth sub-section in which the difference between the current density and the limiting current density decreases. An increase in the difference between the current density and the limiting current density in the fourth section may mean a decrease in the width of the fourth portion P24. A decrease in the difference between the current density and the limiting current density in the fourth section may mean an increase in the width of the fourth portion P24. The fifth sub-section may correspond to a portion where the width of the fourth portion P24 decreases. The sixth sub-section may correspond to a portion where the width of the fourth portion P24 increases.

According to an embodiment, the portion where the width of the fourth portion P24 decreases may be formed by applying a current that increases from the fourth value to a third threshold value during a ninth time interval. The third threshold value may be a value of a current corresponding to the current density for forming a plating film with a minimum width in which the conductive post 170 may electrically operate at an aspect ratio between the fourth aspect ratio AR24 and the fifth aspect ratio AR25.

According to an embodiment, the portion where the width of the fourth portion P24 increases may be formed by applying a current that changes from the third threshold value to the fifth value during a tenth time interval. For example, the third threshold value may be smaller than the fifth value, but the present disclosure is not limited thereto.

According to an embodiment, a sum of the ninth time interval and the tenth time interval may be the eighth time interval.

According to an embodiment, the fourth portion P24 of the conductive post 170 may correspond to the third middle portion 170b_3. A width of the third middle portion 170b_3 may decrease and then increase as the aspect ratio of the opening portion decreases. That is, the width of the third middle portion 170b_3 may decrease and then increase as it moves away from the second middle portion 170b_2.

In a fifth section where the aspect ratio of the opening portion is between the fifth aspect ratio AR25 and a sixth aspect ratio AR26, the current density may be lower than the limiting current density. Because the current density is lower than the limiting current density, the opening portion may be completely filled in the fifth section. The fifth portion P25 of the conductive post 170 may be formed corresponding to the fifth section. A width of the fifth portion P25 may be the same as a width of the opening portion, and may be constant.

According to an embodiment, the fifth portion P25 may be formed by applying a current that changes from the fifth value to a sixth value during an eleventh time interval. Here, the fifth value may be a value of a start current of the fifth section, and the sixth value may be a value of an end current of the fifth section. The value of the start current of the fifth section may be the same as the value of the end current of the fourth section.

According to an embodiment, the current density may increase in the fifth section. That is, the amplitude of the current applied in the fifth section may increase from the fifth value to the sixth value. In the fifth section, the current density may be lower than the limiting current density, so that the opening portion is completely filled and the width of the fifth portion P25 corresponding to the fifth section is constant as the width of the opening portion.

In a sixth section where the aspect ratio of the opening portion is between the sixth aspect ratio AR26 and 0, the current density may be lower than the limiting current density. Because the current density is lower than the limiting current density, the opening portion may be completely filled in the sixth section. The sixth portion P26 of the conductive post 170 may be formed corresponding to the sixth section. A width of the sixth portion P26 may be the same as a width of the opening portion, and may be constant.

According to an embodiment, the sixth portion P26 may be formed by constantly applying a current having the sixth value during a twelfth time interval. Here, the sixth value may be a value of a start current and a value of an end current of the sixth section. The sixth value may be the same as the value of the end current of the fifth section.

According to an embodiment, the current density may be constant in the sixth section. In other words, the amplitude of the current applied in the sixth section may be maintained at the sixth value. In the sixth section, the current density may be lower than the limiting current density, so that the opening portion is completely filled and the width of the sixth portion P26 corresponding to the sixth section is constant as the width of the opening portion.

According to an embodiment, the fifth portion P25 and the sixth portion P26 of the conductive post 170 may correspond to the upper portion 170c. Only amplitudes of currents applied in plating processes forming the fifth portion P25 and the sixth portion P26 may be different, the width of the fifth portion P25 and the width of the sixth portion P26 may be constant, and the width of the fifth portion P25 and the width of the sixth portion P26 may be the same. That is, a width of the upper portion 170c may be constant.

In the embodiment shown in FIGS. 6 to 9, a change in which the horizontal width of the middle portion 170b of the conductive post 170 decreases and then increases is repeated two or three times, but the present disclosure is not limited thereto. In some embodiments, the change in which the width of the middle portion 170b of the conductive post 170 decreases and then increases may be repeated four or more (e.g., five) times.

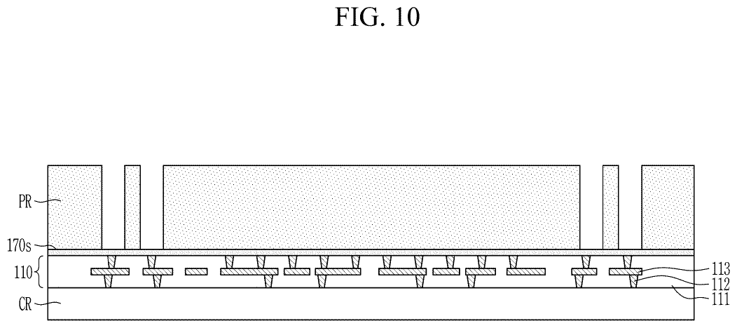

Hereinafter, a manufacturing method of the semiconductor package 100 according to an embodiment will be described with reference to FIGS. 10 to 18.

FIGS. 10 to 18 are schematic cross-sectional views showing intermediate processes in an example manufacturing method of the semiconductor package according to one or more embodiments.

Referring to FIG. 10, the first redistribution structure 110 may be formed on a carrier CR. For example, the carrier CR may include a silicon-based material such as glass or silicon oxide, an organic material, aluminum oxide, or a combination thereof.

The first insulating layer 111 may be deposited on the carrier CR. For example, the first insulating layer 111 may include a photosensitive polymer such as photosensitive polyimide.

Next, via holes may be formed by patterning the first insulating layer 111, and the first redistribution vias 112 may be formed by at least partially filling the via holes with a conductive material.

Next, the first insulating layer 111 may be additionally deposited, the additionally deposited first insulating layer 111 may be patterned to form opening portions, and the opening portions may be at least partially filled with a conductive material to form first redistribution lines 113.

The first redistribution structure 110 including a plurality of layers may be formed by repeating a process of forming the first redistribution vias 112 and the first redistribution lines 113.

Subsequently, a seed layer 170s may be formed on an upper surface of the first redistribution structure 110. The seed layer 170s may include the same material as a metal material forming the conductive post 170s, but the present disclosure is not limited thereto.

Next, a photoresist layer may be formed on the seed layer 170s, and the photoresist layer may be patterned to form a photoresist pattern PR including an opening portion. The opening portion may be formed at a position corresponding to the conductive post 170 to be formed later. The opening portion may be formed at a position that overlaps the first redistribution via 112 on a plane. The term “overlaps” (or “overlapping,” or like terms), as may be used herein, is intended to broadly refer to a first element that intersects with at least a portion of a second element in the vertical direction (i.e., a direction perpendicular to an upper surface of the first redistribution structure 110), but does not require that the first and second elements be completely aligned with one another in a horizontal plane. A portion of the seed layer 170s may be exposed by the opening portion of the photoresist pattern PR.

The opening portion may have an aspect ratio that exceeds a predetermined value. Here, the aspect ratio of the opening portion may mean a ratio of a height of the opening portion along a direction perpendicular to the upper surface of the first redistribution structure 110 to a width of the opening portion along a direction parallel to the upper surface of the first redistribution structure 110. For example, the aspect ratio of the opening portion may exceed 1.5, but the present disclosure is not limited thereto.

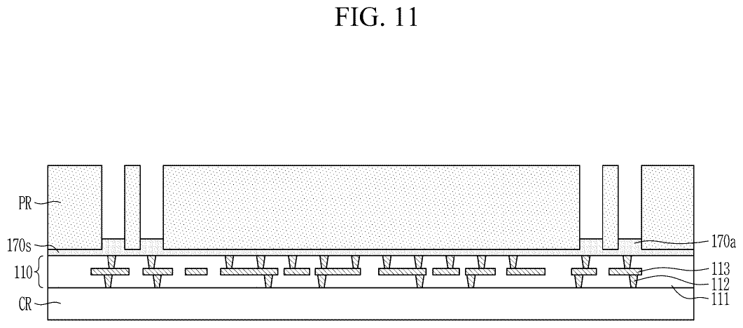

Referring to FIG. 11, an electroplating may be performed to form the lower portion 170a of the conductive post (170 in FIG. 1) within the opening portion. According to an embodiment, the current density may be lower than the limiting current density while the lower portion 170a is formed. A width of the lower portion 170a may be constant. The width of the lower portion 170a may be the same as the width of the opening portion.

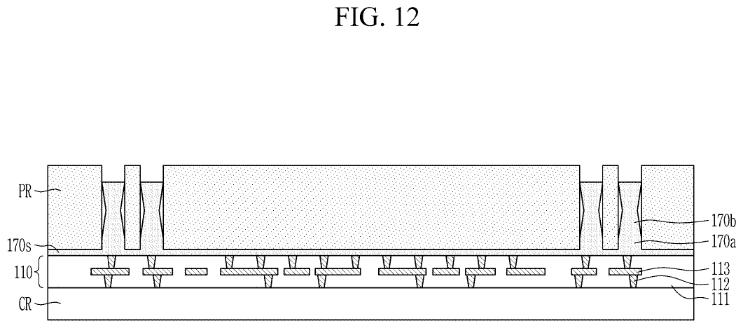

Referring to FIG. 12, an electroplating may be performed to form the middle portion 170b within the opening portion of the photoresist pattern PR. According to an embodiment, the current density may be higher than the limiting current density while the middle portion 170b is formed. According to an embodiment, a difference between the current density and the limiting current density may increase and then decrease while the middle portion 170b is formed. A width of the middle portion 170b may decrease and then increase as it moves away (i.e., vertically upward) from the lower portion 170a. The width of the middle portion 170b may be the same as the width of the opening portion, or may be smaller than the width of the opening portion.

For example, the width of the middle portion 170b may be the same as the width of the opening portion at a point where the middle portion 170b is connected to the lower portion 170a. The width of the middle portion 170b may decrease as it moves away from the lower portion 170a, and may become smaller than the width of the opening portion. The width of the middle portion 170b may increase again if the aspect ratio of the opening portion decreases to a predetermined size or less. The width of the middle portion 170b may increase to become the same as the width of the opening portion.

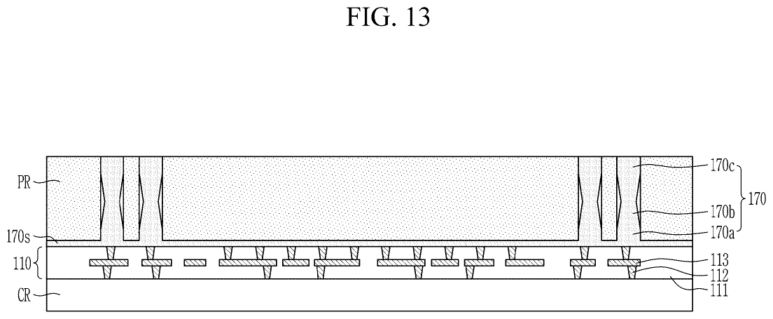

Referring to FIG. 13, an electroplating may be performed to form the upper portion 170c within the opening portion of the photoresist pattern PR. According to an embodiment, the current density may be lower than the limiting current density while the upper portion 170c is formed. A width of the upper portion 170c may be constant. The width of the upper portion 170c may be the same as the width of the opening portion.

The conductive post 170 may be formed by sequentially forming the lower portion 170a, the middle portion 170b, and the upper portion 170c. For example, the conductive post 170 may include a metal material such as copper (Cu), but the present disclosure is not limited thereto, and the conductive post 170 may include various conductive materials.

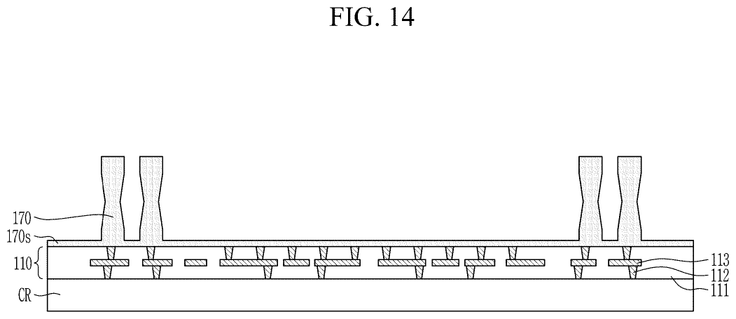

Referring to FIG. 14, the photoresist pattern PR may be removed.

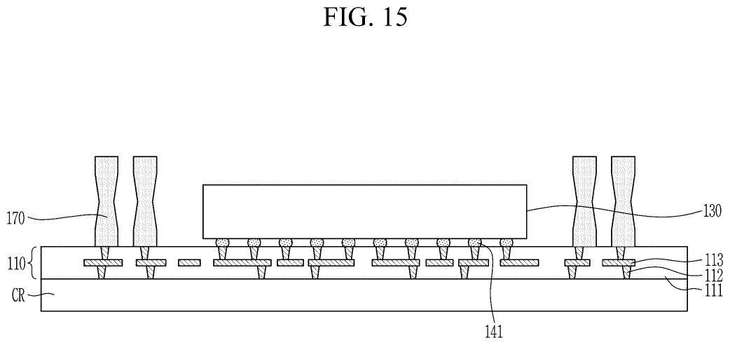

Referring to FIG. 15, the seed layer 170s may be partially etched, and the first semiconductor chip 130 may be mounted above the first redistribution structure 110.

For example, a portion of the seed layer 170s disposed on an upper surface of the first redistribution structure 110 and not covered by the conductive posts 170 may be removed. Only a portion of the seed layer 170s disposed between the conductive post 170 and the first redistribution structure 110 may remain.

The first semiconductor chip 130 may be bonded above the first redistribution structure 110. The first semiconductor chip 130 may be connected to the first redistribution via 112 of the first redistribution structure 110 through the plurality of first connection members 141. For example, the first connection member 141 may include a micro-bump.

Although only one semiconductor chip is shown in FIG. 15, the present disclosure is not limited thereto, and a plurality of semiconductor chips may be mounted above the first redistribution structure 110.

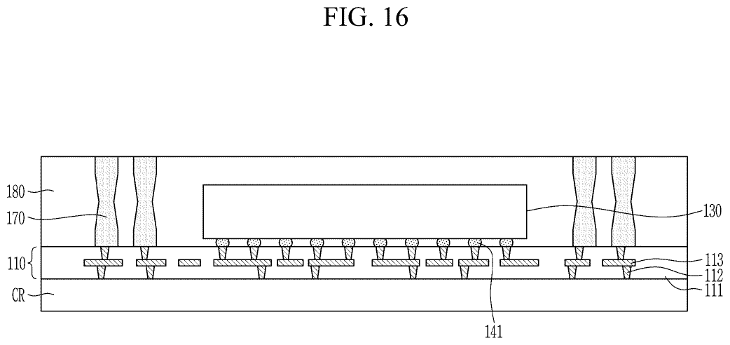

Referring to FIG. 16, the molding member 180 covering the first redistribution structure 110 and the first semiconductor chip 130 may be formed. The molding member 180 may surround (i.e., extend around) a side surface of the conductive posts 170. The molding member 180 may surround the first connection members 141 between the first semiconductor chip 130 and the first redistribution structure 110.

According to an embodiment, the molding member 180 may be formed to cover an upper surface of the conductive post 170, and then may be planarized to have the same upper surface as that of the conductive post 170 through a chemical mechanical polishing (CMP) process or the like. After planarization, an upper surface of the molding member 180 may be horizontally coplanar with the upper surface of the conductive posts 170.

For example, the molding member 180 may include an epoxy molding compound (EMC), but the present disclosure is not limited thereto.

The conductive post 170 may have a structure in which a width thereof is constant in the lower portion 170a, decreases and then increases in the middle portion 170b, and is constant again in the upper portion 170c. Accordingly, a side surface of the conductive post 170 may include a curved portion, and the molding member 180 in a liquid state may flow well along the curved portion of the side surface of the conductive post 170.

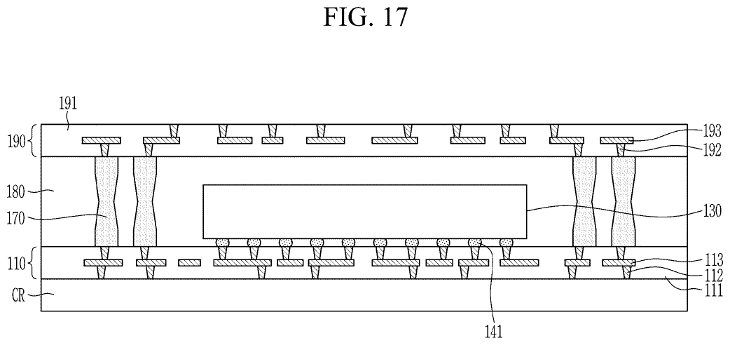

Referring to FIG. 17, the second redistribution structure 190 may be formed on the molding member 180 and the conductive posts 170. A formation method of the second redistribution structure 190 may be the same as the formation method of the first redistribution structure 110 described above. The second redistribution structure 190 may include the second insulating layer 191, the plurality of second redistribution vias 192, and the plurality of second redistribution lines 193.

The conductive post 170 may electrically connect the first redistribution structure 110 and the second redistribution structure 190. The conductive post 170 may be electrically connected to the first redistribution via 112 and the second redistribution via 192.

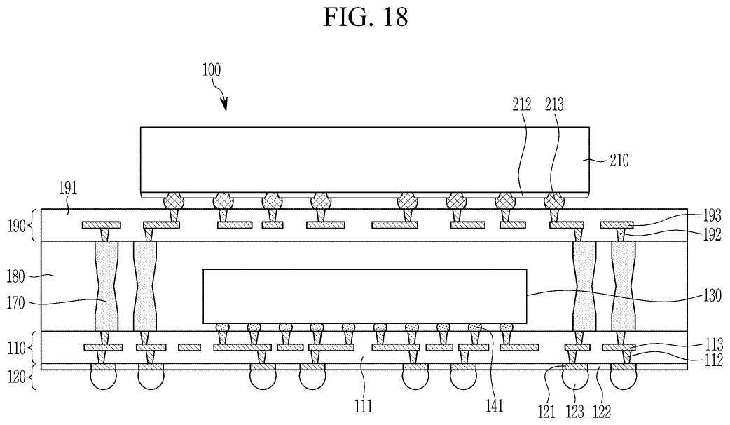

Referring to FIG. 18, the carrier CR may be removed, and the external connection structure 120 may be formed on a lower surface of the first redistribution structure 110. The external connection structure 120 may include the pad insulating layer 122, the plurality of conductive pads 121 buried (or embedded) in a lower surface of the pad insulating layer 122, and the plurality of external connection members 123 connected to the plurality of conductive pads 121. For example, the external connection member 123 may include a solder ball or a solder bump.

Additionally, the second semiconductor chip 210 may be mounted above the second redistribution structure 190. The second semiconductor chip 210 may be bonded above the second redistribution structure 190. The second semiconductor chip 210 may include the plurality of second connection members 213 and the insulating layer 212. The second semiconductor chip 210 may be connected to the second redistribution structure 190 through the plurality of second connection members 213. For example, the second connection member 213 may include a micro-bump or a solder ball. The insulating layer 212 may include an opening portion. The second connection member 213 may be connected to the second semiconductor chip 210 through the opening portion of the insulating layer 212. For example, the insulating layer 212 may include a solder resist.

The semiconductor package 100 according to the embodiment may be manufactured through the processes shown in FIGS. 10 to 18.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package, comprising:
a first redistribution structure;
a semiconductor chip on the first redistribution structure;
a molding member on the first redistribution structure and the semiconductor chip;
a second redistribution structure on the molding member; and
a conductive post between the first redistribution structure and the second redistribution structure that electrically connects the first redistribution structure and the second redistribution structure,
wherein the conductive post includes a lower portion connected to the first redistribution structure, an upper portion connected to the second redistribution structure, and a middle portion between the lower portion and the upper portion, the lower portion, the middle portion and the upper portion being sequentially stacked in a vertical direction perpendicular to an upper surface of the first redistribution structure, and a width of the middle portion in a horizontal direction parallel to the upper surface of the first redistribution structure is not constant.

2. The semiconductor package of claim 1, wherein the width of the middle portion decreases and then increases with increasing distance in the vertical direction from the lower portion to the upper portion.

3. The semiconductor package of claim 1, wherein the middle portion includes a first middle portion and a second middle portion on the first middle portion in the vertical direction on an upper surface of the first redistribution structure, and each of a width of the first middle portion and a width of the second middle portion in the horizontal direction decreases and then increases from the lower portion to the upper portion.

4. The semiconductor package of claim 3, wherein the middle portion further includes a third middle portion on the second middle portion in the vertical direction on the upper surface of the first redistribution structure with respect to the first middle portion and the second middle portion, and a width of the third middle portion in the horizontal direction decreases and then increases from the lower portion to the upper portion.

5. The semiconductor package of claim 1, wherein each of a width of the lower portion and a width of the upper portion in the horizontal direction is constant.

6. The semiconductor package of claim 1, wherein the width of the middle portion is equal to or less than a width of the lower portion and is equal to or less than a width of the upper portion.

7. A semiconductor package, comprising:
a first redistribution structure;
a first semiconductor chip on an upper surface of the first redistribution structure;
a molding member on the first redistribution structure and the semiconductor chip;
a second redistribution structure on the molding member;
a second semiconductor chip on the second redistribution structure;
an external connection structure on a lower surface of the first redistribution structure; and
a plurality of conductive posts between the first redistribution structure and the second redistribution structure that electrically connect the first redistribution structure to the second redistribution structure,
wherein each of the plurality of conductive posts includes a lower portion connected to the first redistribution structure, an upper portion connected to the second redistribution structure, and a middle portion between the lower portion and the upper portion, a width of the lower portion in a horizontal direction, parallel to an upper surface of the first redistribution structure, and a width of the upper portion in the horizontal direction are constant, and a width of the middle portion in the horizontal direction is not constant.

8. The semiconductor package of claim 7, wherein the width of the middle portion decreases and then increases with increasing distance in a vertical direction, perpendicular to the upper surface of the first redistribution structure, from the lower portion to the upper portion.

9. The semiconductor package of claim 7, wherein the middle portion includes a first middle portion and a second middle portion stacked in a vertical direction on the upper surface of the first redistribution structure, and each of a width of the first middle portion and a width of the second middle portion in the horizontal direction decreases and then increases with increasing distance in the vertical direction from the lower portion to the upper portion.

10. The semiconductor package of claim 9, wherein the middle portion further includes a third middle portion stacked in the vertical direction on the upper surface of the first redistribution structure with respect to the first middle portion and the second middle portion, and a width of the third middle portion in the horizontal direction decreases and then increases with increasing distance in the vertical direction from the lower portion to the upper portion.

11. The semiconductor package of claim 7, wherein the width of the middle portion is equal to or less than the width of the lower portion and is equal to or less than the width of the upper portion.

12. A manufacturing method of a semiconductor package, the manufacturing method comprising:
forming a first redistribution structure on one surface of a carrier substrate;
forming a seed layer on an upper surface of the first redistribution structure;
forming a photoresist pattern including an opening portion on the seed layer; and
forming a conductive post by plating a conductive material within the opening portion of the photoresist pattern,
wherein forming the conductive post includes forming a lower portion of the conductive post by plating with a current density less than a limiting current density, forming a middle portion of the conductive post by plating with a current density greater than the limiting current density, and forming an upper portion of the conductive post by plating with the current density less than the limiting current density, and the limiting current density is a maximum current density at which a plating material completely fills the opening portion.

13. The manufacturing method of claim 12, wherein forming the middle portion of the conductive post comprises applying a current that changes from a first amplitude value to a second amplitude value during a first time interval.

14. The manufacturing method of claim 13, wherein forming the middle portion of the conductive post further comprises increasing and then decreasing a difference between the current density and the limiting current density.

15. The manufacturing method of claim 12, wherein forming the middle portion of the conductive post comprises:
forming a first middle portion by applying a current that changes from a first amplitude value to a second amplitude value during a first time interval; and
forming a second middle portion by applying a current that changes from the second amplitude value to a third amplitude value during a second time interval,
wherein in each of the forming of the first middle portion and the forming of the second middle portion, a difference between the current density and the limiting current density increases and then decreases.

16. The manufacturing method of claim 15, wherein forming the middle portion of the conductive post further comprises forming a third middle portion by applying a current that changes from the third amplitude value to a fourth amplitude value during a third time interval,
wherein in forming the third middle portion, a difference between the current density and the limiting current density increases and then decreases.

17. The manufacturing method of claim 12, wherein forming the upper portion of the conductive post comprises:
applying a current having a first amplitude value during a first time interval; and
applying a current having a second amplitude value greater than the first amplitude value during a second time interval.

18. The manufacturing method of claim 12, wherein forming the upper portion of the conductive post comprises:
applying a current that changes from a first amplitude value to a second amplitude value during a first time interval; and
applying a current having the second amplitude value during a second time interval.

19. The manufacturing method of claim 12, wherein forming the lower portion of the conductive post comprises applying a current that changes from a first amplitude value to a second amplitude value during a first time interval.

20. The manufacturing method of claim 12, wherein forming the lower portion of the conductive post comprises:
applying a current having a first amplitude value during a first time interval; and
applying a current that changes from the first amplitude value to a second amplitude value during a second time interval.
